(19) United States
(12) Patent Application Publication
(10) Pub. No.: US 2026/0198295 A1
(43) Pub. Date: Jul. 9, 2026

(54) FRONTSIDE BEOL NETWORK CONNECTION TO BSPDN

(71) Applicant: INTERNATIONAL BUSINESS MACHINES CORPORATION, Armonk, NY (US)

(72) Inventors: Tsung-Sheng Kang, Ballston Lake, NY (US); Tao Li, Slingerlands, NY (US); Ruilong Xie, Niskayuna, NY (US); Albert Manhee Chu, Nashua, NH (US)

(21) Appl. No.: 19/009,177

(22) Filed: Jan. 3, 2025

(51) Int. Cl. H10W 20/41; H10D 30/00; H10D 30/01; H10D 30/43; H10D 62/10

(52) U.S. Cl. CPC H10W 20/435; H10D 30/014; H10D 30/019; H10D 30/43; H10D 30/501; H10D 62/121; H10W 20/427

(57) ABSTRACT

A semiconductor device includes a frontside and a backside. A first conductor on the frontside is disposed in a first track, and a second conductor on the backside is disposed in a second track which is offset from the first track. A local interconnect connects the first conductor to the second conductor. The local interconnect includes a vertical portion that connects components on different layers and a horizontal portion extending laterally from the vertical portion and extending between the first track and the second track.

### RELATED APPLICATION INFORMATION

This application is related to an application entitled “FRONTSIDE BEOL NETWORK CONNECTION TO BSPDN”, having attorney docket number P202401891AUS01 (2955) and which is incorporated by reference herein in its entirety.

### BACKGROUND

The present invention generally relates to semiconductor devices and processing methods, and more particularly to direct connections between a frontside and a backside of a semiconductor device.

Semiconductor devices that utilize backside power distribution networks (BSPDN) often need to communicate with devices or networks on a frontside of the device. While this can be accomplished by using a deep via when connections share a same track, connecting to circuit components on a different track (e.g., laterally offset) is difficult and can consume an inordinate amount of layout area. Positioning devices and connections becomes increasingly more difficult with high density device chips. This is particularly true with frontside layouts which tend to be exceedingly dense.

### SUMMARY

In accordance with an embodiment of the present invention, a semiconductor device includes a frontside and a backside. A first conductor on the frontside is disposed in a first track, and a second conductor on the backside is disposed in a second track which is offset from the first track. A local interconnect connects the first conductor to the second conductor. The local interconnect includes a vertical portion that connects components on different layers and a horizontal portion extending laterally from the vertical portion and extending between the first track and the second track.

In accordance with another embodiment of the present invention, a semiconductor device includes a frontside and a backside. A first conductor on the frontside is disposed in a first track, and a second conductor on the backside is disposed in a second track which is offset from the first track. A local interconnect connects the first conductor to the second conductor. The local interconnect includes a horizontal portion that connects a backside contact to a vertical portion of the local interconnect. The horizontal portion extends laterally over multiple tracks to connect between the first conductor in the first track and the second conductor in the second track.

In accordance with another embodiment of the present invention, a method of forming a semiconductor device includes forming a diffusion break cut through a source/drain region; depositing a conductive material in the diffusion break cut; forming the conductive material to extend horizontally and vertically to connect horizontally offset components; and connecting a first conductor disposed in a first track on a frontside of the semiconductor device to a second conductor on a backside of the semiconductor device disposed in a second track which is offset from the first track.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows cross-sectional views, taken at section lines X and Y as shown in an inset (and referred to as section X and section Y, respectively), of a semiconductor substrate with dummy gate structures and source/drain (S/D) regions formed, in accordance with an embodiment of the present invention;

FIG. 2 shows cross-sectional views, taken at section lines X and Y, with a S/D region removed to form a diffusion break cut and to expose a sacrificial placeholder, in accordance with an embodiment of the present invention;

FIG. 3 shows cross-sectional views, taken at section lines X and Y, showing inner spacers formed inside the diffusion break cut where the S/D region was removed, in accordance with an embodiment of the present invention;

FIG. 4 shows cross-sectional views, taken at section lines X and Y, after formation of a dielectric layer, in accordance with an embodiment of the present invention;

FIG. 5 shows cross-sectional views, taken at section lines X and Y, after replacement metal gates are formed, in accordance with an embodiment of the present invention;

FIG. 6 shows cross-sectional views, taken at section lines X and Y, after formation of middle of the line contacts and a local interconnect, in accordance with an embodiment of the present invention;

FIG. 7 shows cross-sectional views, taken at section lines X and Y, after etching the local interconnect to form an L-shaped conductor to provide a connection between offset tracks, in accordance with an embodiment of the present invention;

FIG. 8 shows cross-sectional views, taken at section lines X and Y, after formation of a dielectric material over the local interconnect, in accordance with an embodiment of the present invention;

FIG. 9 shows cross-sectional views, taken at section lines X and Y, after back end of the line structures are formed, a carrier wafer is applied and the structure is flipped to process the backside and backside interconnect structures are formed, in accordance with an embodiment of the present invention;

FIG. 10 shows cross-sectional views, taken at section lines X and Y, after a tilted opening is formed in a dielectric layer, in accordance with an embodiment of the present invention;

FIG. 11 shows cross-sectional views, taken at section lines X and Y, after a tilted conductor is formed in the tilted opening to provide a connection between offset tracks, in accordance with an embodiment of the present invention;

FIG. 12 shows cross-sectional views, taken at section lines X and Y, after gate cuts are formed, in accordance with an embodiment of the present invention;

FIG. 13 shows cross-sectional views, taken at section lines X and Y, after a diffusion break cut is formed in a gate canyon, in accordance with an embodiment of the present invention;

FIG. 14 shows cross-sectional views, taken at section lines X and Y, after the diffusion break cut is extended into the semiconductor layer and filled with a conductor, in accordance with an embodiment of the present invention;

FIG. 15 shows cross-sectional views, taken at section lines X and Y, after the sacrificial placeholders are exposed by removing the substrate and the semiconductor layer, in accordance with an embodiment of the present invention;

FIG. 16 shows cross-sectional views, taken at section lines X and Y, after depositing a layer to fill a gap between the sacrificial placeholder and the conductor in the diffusion break cut, in accordance with an embodiment of the present invention;

FIG. 17 shows cross-sectional views, taken at section lines X and Y, after depositing a dielectric and recessing the dielectric layer to expose the sacrificial placeholders, the conductor in the diffusion break cut and a plug formed in the gap, in accordance with an embodiment of the present invention;

FIG. 18 shows cross-sectional views, taken at section lines X and Y, after removing the plug formed in the gap, in accordance with an embodiment of the present invention;

FIG. 19 shows cross-sectional views, taken at section lines X and Y, after removing the sacrificial placeholders, in accordance with an embodiment of the present invention; and

FIG. 20 shows cross-sectional views, taken at section lines X and Y, after forming contacts and an angled conductor to provide a connection between offset tracks, in accordance with an embodiment of the present invention.

### DETAILED DESCRIPTION

In accordance with embodiments of the present invention, devices and methods are described which include connections between a frontside and a backside of a semiconductor device. Conductive structures are provided to span lateral distances to make connections between components that are on different tracks or are otherwise laterally offset from one another. In an embodiment, an L-shaped connection can be formed between a backside contact and a frontside back end of the line (BEOL) via, which permits a more relaxed patterning process by providing flexibility as to where connections across the device can be made. Interconnections between backside contacts and frontside contacts can include a horizontal section between a bottom of source/drain (S/D) canyons. In an embodiment, the horizontal section can include a height (thickness) below about 30 nm to reduce capacitance. In an embodiment, a tilted connection can be included between backside contacts and frontside BEOL structures. This permits relaxation of patterning processes and reduces an amount of metal within the structure to help reduce capacitance. A double diffusion break region can be included having the L-shaped metal inside to provide a region where a turn can extend to make the connection.

In accordance with an embodiment, a semiconductor device includes an L-shaped connection between a backside contact and back end of line (BEOL) vias. The L-shaped connection between the backside contact and a frontside via has a horizontal section in a source/drain (S/D) canyon. The height of the horizontal section is below about 30 nm. In another embodiment, a semiconductor device includes a tilted connection between a backside contact and BEOL vias.

In an embodiment, a method for fabricating a semiconductor device includes forming a double diffusion break region and a S/D region cut landing over a backside contact placeholder, after forming gates, S/D regions and placeholders. Inner spacers are formed by recessing channel sheets. A local interconnect is formed within the double diffusion break region, landing over the backside contact placeholder. A top of the local interconnect connects to a frontside metal layer (e.g., M1). The backside contact placeholder is replaced under the local interconnect to the backside contact. A portion of the local interconnect is removed to reduce capacitance. The backside contact is connected to a backside metal layer (e.g., M1).

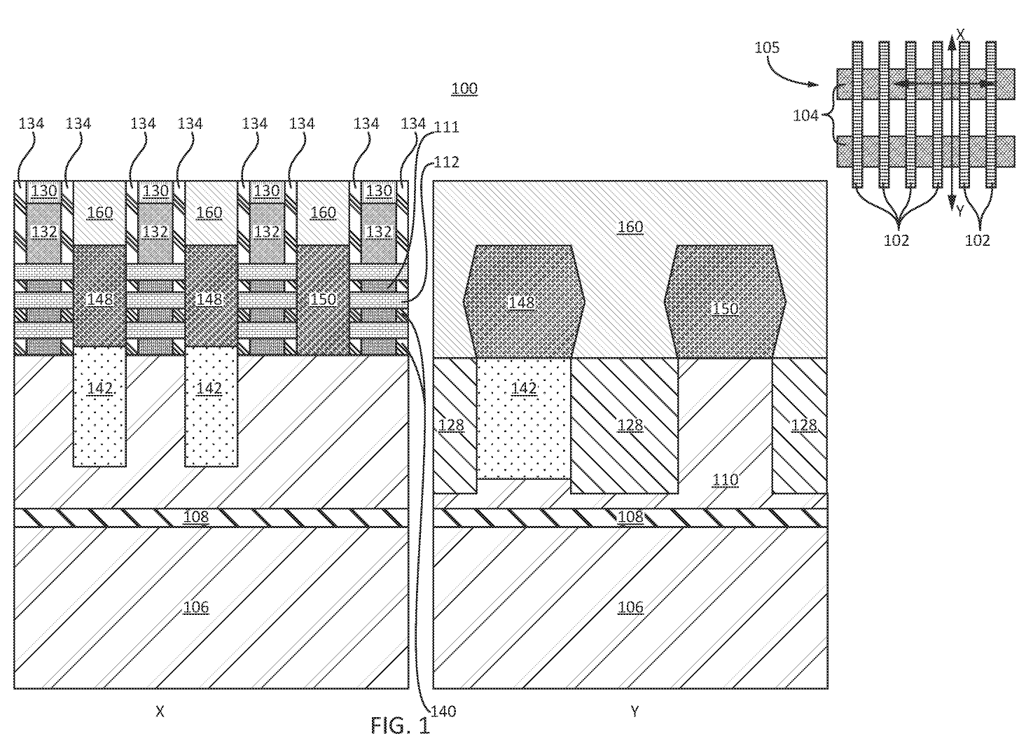

Referring now to the drawings in which like numerals represent the same or similar elements and initially to FIG. 1, devices and methods for manufacturing a nanosheet field effect transistor (FET) device are shown in accordance with embodiments of the present invention. A wafer 100 includes a substrate 106 having one or more layers on which the FET device will be fabricated. FIG. 1 depicts two orthogonal views X and Y taken at corresponding sections X and Y in inset 105. Inset 105 shows gate lines 102 and active region lines 104 for reference. Corresponding X and Y views are depicted throughout the FIGS. Active region lines 104 represent S/D regions for transistor devices to be formed, and gate lines 102 are represented for such transistor devices. Transistor channels are formed on the active region lines 104 below the gate lines 102.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In an embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A nanosheet stack or stacks is/are applied to or formed on the semiconductor layer 110. In an embodiment, nanosheets 111, 112 are included in the nanosheet stack. The nanosheets 111, 112 include alternating semiconductor layers of different semiconductor materials. The alternating layers can be epitaxially grown using different chemistries to form layers having different properties. In an embodiment, the semiconductor layers of the nanosheets 112 form transistor channels and can include, e.g., Si, although other semiconductor materials can be employed. The semiconductor layers of the nanosheets 111 can include sacrificial layers and can include, e.g., SiGe.

A single or multiple nanosheet stack can be patterned to expose and etch the semiconductor layer 110. In an embodiment, a hard mask (not shown) may be formed by blanket depositing a layer of hard mask material, providing a patterned photoresist on top of the layer of hard mask material, and then etching the layer of hard mask material to provide the hard mask pattern for etching the nanosheet stack. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Semiconductor layer 110 is further etched to form shallow trenches therein. Shallow trench isolation (STI) regions or STI 128 are formed in the etched trenches. STI 128 can be formed by depositing dielectric material, such as, e.g., SiO₂, SiOₓN_{y}, SiCO or other suitable compounds. STI 128 can be deposited using chemical vapor deposition (CVD), although other deposition methods can be employed. The STI 128 can then be etched, e.g., by RIE, to a level of the semiconductor layer 110.

A dummy gate material 132 for dummy gates is blanketed over the wafer 100 followed by a blanket deposition of a hard mask material to later form patterned hard mask 130, e.g., by using photolithographic patterning. The dummy gate material 132 can include a polysilicon, amorphous Si or other selectively removeable material. The hard mask material is patterned to form hard mask 130. The hard mask 130 is employed to etch the dummy gate material 132. Then, a deposition process is employed to form spacers 134. Spacers 134 can include a nitride, an oxide, such as silicon dioxide, although other dielectric materials can be employed.

The hard mask 130 and spacers 134 can be employed as an etch mask to recess the nanosheet stack to expose semiconductor layer 110. Regions of the nanosheet stack below the hard mask 130 and spacers 134 are patterned for further processing.

Inner spacers 140 are formed and include a dielectric material. In an embodiment, the inner spacers 140 are formed using exposed portions of the nanosheets 111, which undergo a recess etch followed by a sidewall deposition of a dielectric (e.g., SiO₂) in recessed portions.

The hard mask 130 and spacers 134 can be employed as an etch mask to recess the semiconductor layer 110 in selected locations. The semiconductor layer 110 is recessed to form trenches by an anisotropic etch, e.g., a reactive ion etch (RIE) or an ion beam etch (IBE). Within the trenches recessed into the semiconductor layer 110, a sacrificial placeholder 142 is formed. The sacrificial placeholder 142 can be epitaxially grown in the trenches of semiconductor layer 110. The sacrificial placeholder 142 can include SiGe or other epitaxial grown material that can be selectively removed relative to the semiconductor layer 110.

An epitaxial growth process is performed to form source and drain (S/D) regions 148 and 150. S/D regions 148 and 150 are employed to form transistors of the semiconductor device under construction. S/D regions 148 and 150 can include Si or SiGe and include faceted surfaces when epitaxial growth is not confined. In an embodiment, the S/D regions 148 and 150 can be designated as P-type or N-type devices. The P-type and N-type devices can include an appropriately selected material. For example, if the S/D regions 148 and 150 include N-type devices then the S/D regions 148 and 150 can include Si. In another example, if the S/D regions 148 and 150 include P-type devices then the S/D regions 148 and 150 can include SiGe. The S/D regions 148 and 150 can be appropriately doped during their formation by epitaxial growth. For example, the S/D regions 148 and 150 can be doped by introducing p dopants (e.g., B, Ga, etc.) during epitaxial formation. Similarly, the S/D regions 148 and 150 can be doped by introducing n dopants (e.g., P, As, etc.) during epitaxial formation. In other embodiments, P-type and N-type devices can be formed adjacent to one another. Processing can include forming one device type and then the other device type by employing block masks to protect each device during the processing of the other.

A dielectric layer 160, such as, e.g., an interlevel dielectric layer (ILD) is formed on the wafer 100. The dielectric layer 160 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK^{TM}, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using CVD, although other deposition methods can be employed.

The dielectric layer 160 is then recessed by an etch back process that removes the dielectric layer 160 evenly (level) across the wafer 100.

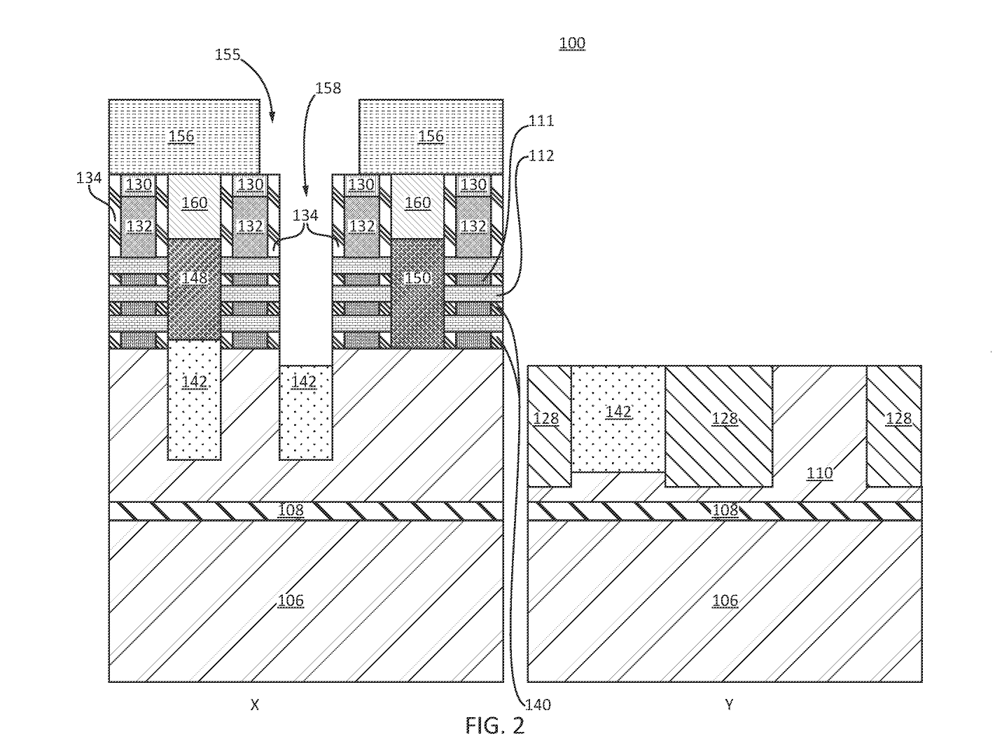

Referring to FIG. 2, an etch mask 156 is formed on a surface of the wafer 100. In an embodiment, the etch mask can include an organic polymer layer (OPL). In some embodiments, an anti-reflective coating (ARC) layer (not shown) may be formed on the OPL of the etch mask 156 followed by a layer of photoresist formed on the ARC layer. The layer of photoresist can be imaged with an image pattern and developed to form an etch mask.

The OPL of the etch mask 156 can be etched in accordance with the photoresist pattern to open up a double diffusion break cut 155 in the OPL of the etch mask 156 and remove the S/D regions 148 and 150. The double diffusion break cut 155 can be formed by an anisotropic etch, e.g., a RIE etch or IBE etch. Etching of the OPL of the etch mask 156 in accordance with the etch mask may include an etch chemistry for removing the OPL of the etch mask 156 and S/D regions 148 and 150 within a S/D canyon 158. The etch mask 156 is removed. If the etch mask 156 includes OPL, an ashing process can be employed to remove the OPL.

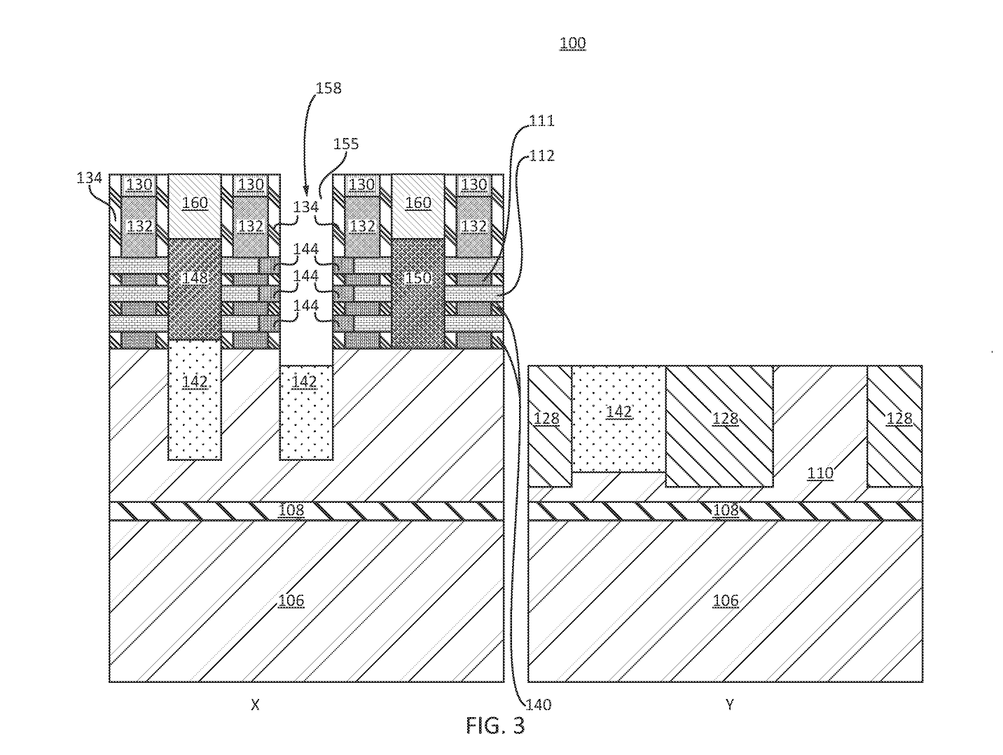

Referring to FIG. 3, the S/D canyon 158 is etched within the double diffusion break cut 155 to laterally recess the nanosheets 112. The recesses formed are then filled with a dielectric material by performing a dielectric deposition. The dielectric deposition (e.g., CVD) forms a dielectric material in the recesses. An etch process removes any residual dielectric material (e.g., an oxide) from the dielectric deposition to form inner spacers 144.

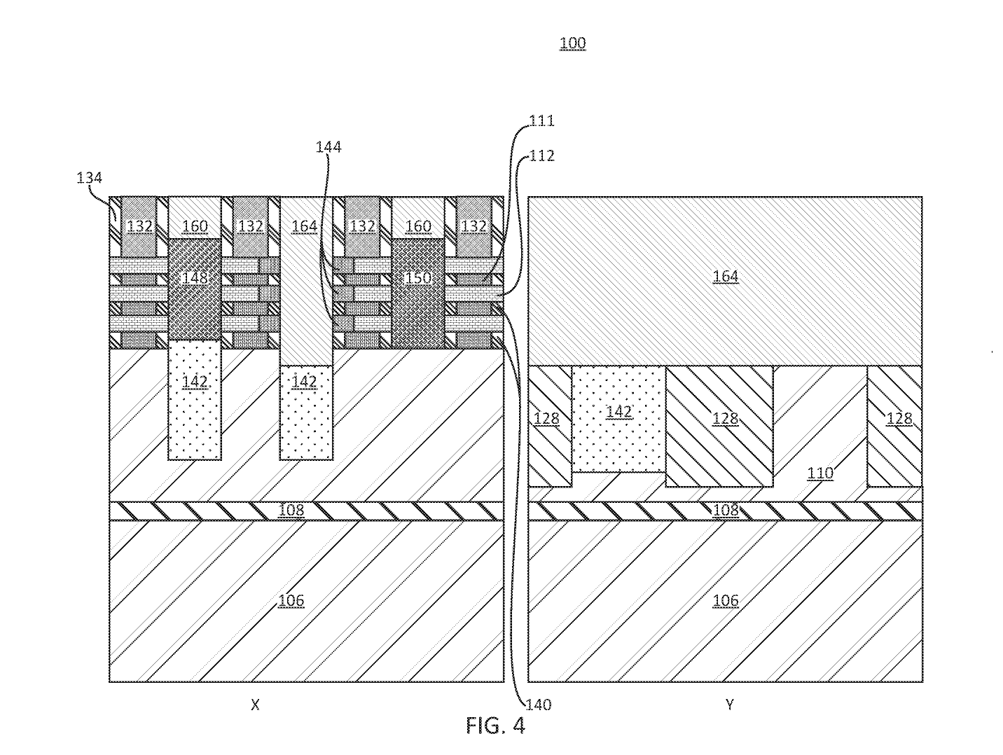

Referring to FIG. 4, a dielectric layer 164 is deposited over the wafer 100. The same process used for the formation of dielectric layer 160 can be employed for the dielectric layer 164, although the dielectric layer 164 may include a different composition to enable etch selectivity. For example, if the dielectric layer 160 includes a silicon oxide, the dielectric layer 164 can include a silicon nitride to be selectively etchable with respect to the dielectric layer 160. The dielectric layer 164 is planarized, e.g., by CMP, which also removes the hard mask 130 and portions of the spacers 134 to expose the dummy gate material 132.

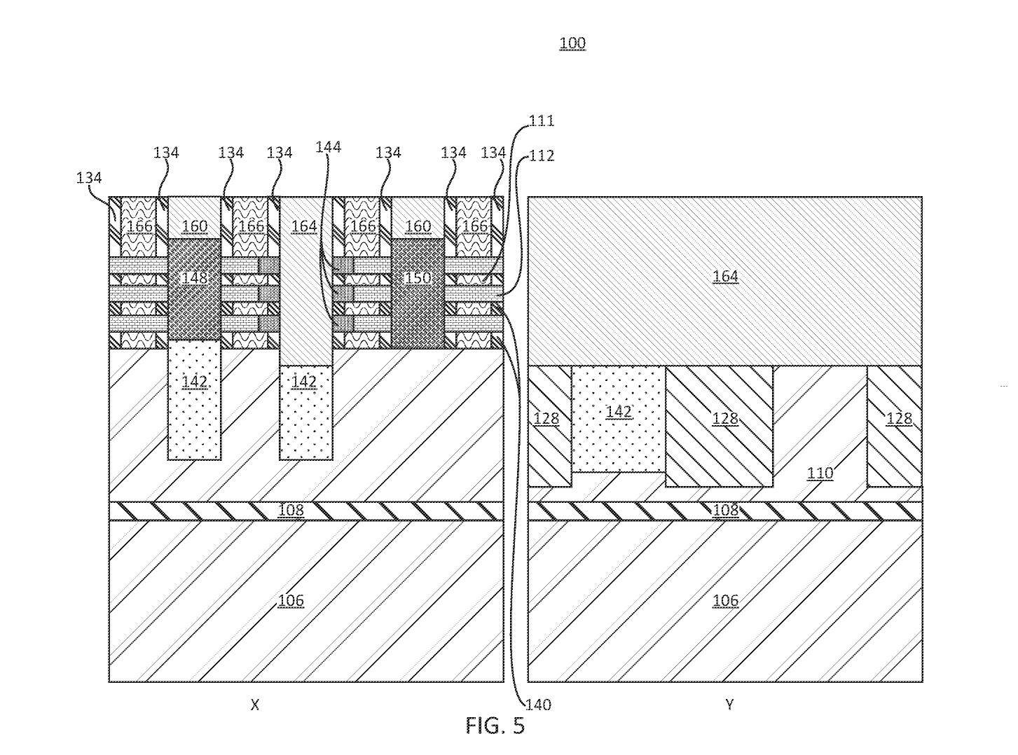

Referring to FIG. 5, the dummy gate material 132 and the nanosheets 111 are removed by etching. This can include separate etch processes. The regions of the dummy gate material 132 and the nanosheets 111 have a high dielectric constant (high-K) gate dielectric (not shown) formed followed by a gate metal fill to form gate conductors 166 in a replacement metal gate (RMG) process. The RMG process forms High-K Metal Gate (HKMG) structures for selectively activating FETs. The gate conductor 166 can include any conductive material including, but not limited to W, Ni, Ti, Mo, Ta, Cu, Pt, Ag, Au, Ru, Ir, Rh, and Re, and alloys that include at least one of these conductive materials. The gate conductor 166 can include one or more layers of conductive materials. In one example, a second conductive material may be formed. When a combination of conductive elements is employed, an optional diffusion barrier material such as TaN or WN may be formed between the conductive materials. The gate conductor 166 can be deposited by CVD, plasma enhanced CVD (PECVD), ALD or other suitable deposition process. A planarization process (e.g., CMP) can be employed to planarize a free surface of the wafer 100.

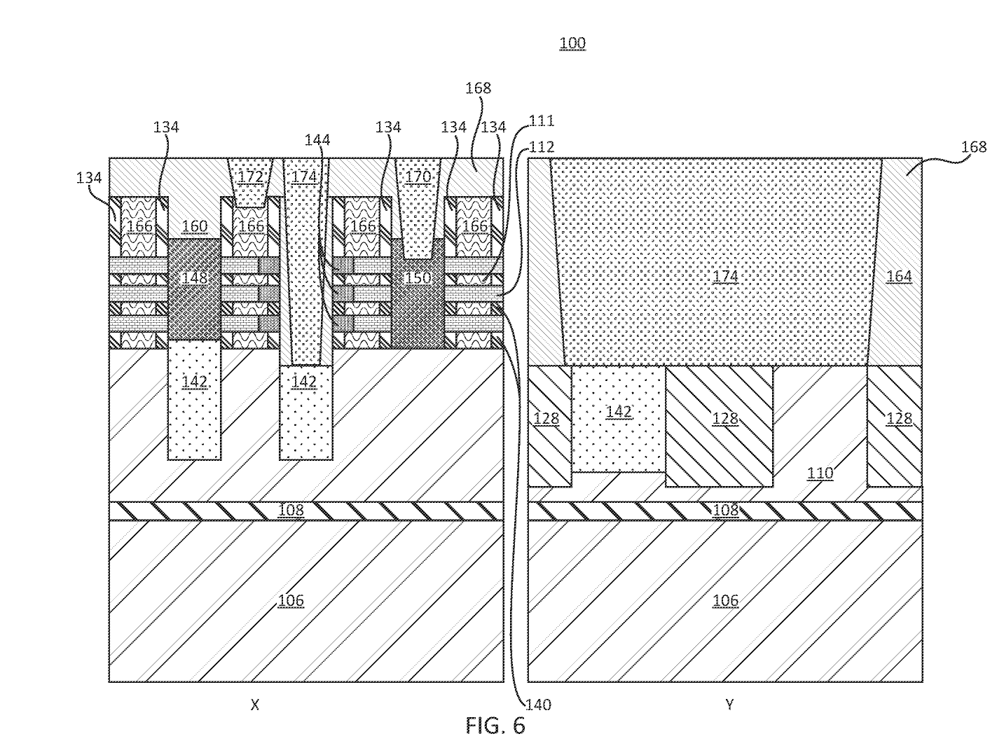

Referring to FIG. 6, middle of the line (MOL) contacts are formed to make connections with gate conductors 166, S/D region 150 (and S/D regions 148 in other regions) and the sacrificial placeholders 142. The dielectric layer 164 is extended by depositing additional dielectric material 168 over the wafer 100. Trenches or holes are formed through the additional dielectric material 168 and the dielectric layer 164. The trenches or holes expose the underlying components to be contacted.

In useful embodiments, a silicide liner, such as Ti, Ni, NiPt is deposited first where contacts connect to S/D regions 148 and 150. A diffusion barrier can be formed in all trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 170, 172 and local interconnect 174.

The contacts 170, 172 and local interconnect 174 can be processed together, in combination or separately. For example, in an embodiment, the contacts 170, 172 and local interconnect 174 can have openings etched using different etch masks but can employ a common conductive fill and be filled together. In other embodiments, each of the contacts 170, 172 and local interconnect 174 can be fabricated in a separate processing sequence. The local interconnect 174 extends across active regions (e.g., RX) to make lateral connections as will be described.

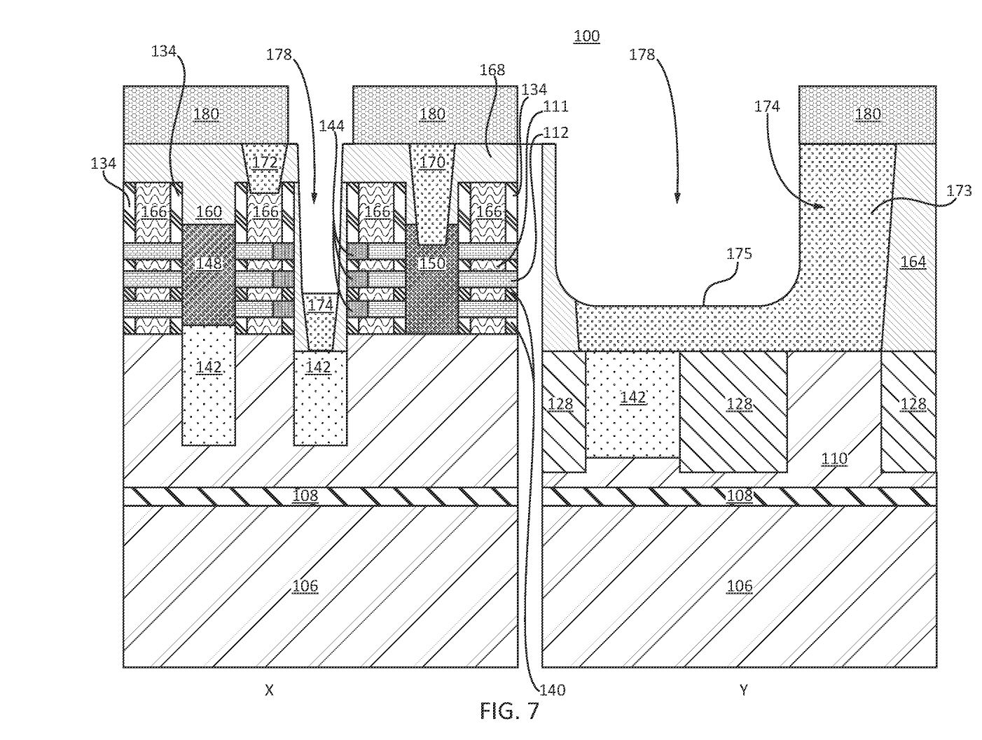

Referring to FIG. 7, an etch mask 180 is applied, e.g., spun onto the wafer 100. The etch mask 180 can include, e.g., a photoresist. The etch mask 180 can be processed using lithographic processing. Trenches 178 or holes can be patterned using photolithographic patterning techniques to create an etch mask to etch the trenches 178 using an anisotropic etch., e.g., RIE. The trenches 178 are formed by removing material of the dielectric layer 164 and portions of the local interconnect 174. The local interconnect 174 can be subtractively etched to form an L-shape to reduce capacitance with surrounding conductors by removing access metal material. The etch recesses a portion of the local interconnect 174 to form a vertical portion 173 and a horizontal portion 175. The vertical portion 173 and the horizontal portion 175 are therefore integrally formed from a same material and process so that no material or processing interfaces are present in the local interconnect 174.

The horizontal portion 175 permits connections across component tracks while the vertical portion 173 permits connections between layers. Component tracks or tracks refers to parallel linear regions or paths on a semiconductor device layout where circuit components, interconnects, or other structures are arranged. Tracks may be aligned in a grid-like pattern and may extend in horizontal and/or vertical directions. Tracks may define standardized locations for placing and routing various elements of an integrated circuit design, such as transistors, contacts, vias, or metal lines. Tracks may help organize the layout of a semiconductor device and facilitate efficient use of space and connectivity between different components.

The local interconnect 174 contacts the sacrificial placeholders 142 and the semiconductor layer 110 as shown in section Y of FIG. 7. The vertical portion 173 spans different layers, and the horizontal portion 175 extends laterally from the vertical portion 173 and extends over multiple tracks. In an embodiment, the vertical portion 173 has a width less than or equal to a cell height of a track that it occupies. This provides a low resistance path since the vertical portion can be formed with a wide dimension. The vertical portion 173 can include a width larger than a height of the horizontal portion 175. In an embodiment, the horizontal portion 175 can include a height (thickness) below about 30 nm to reduce capacitance.

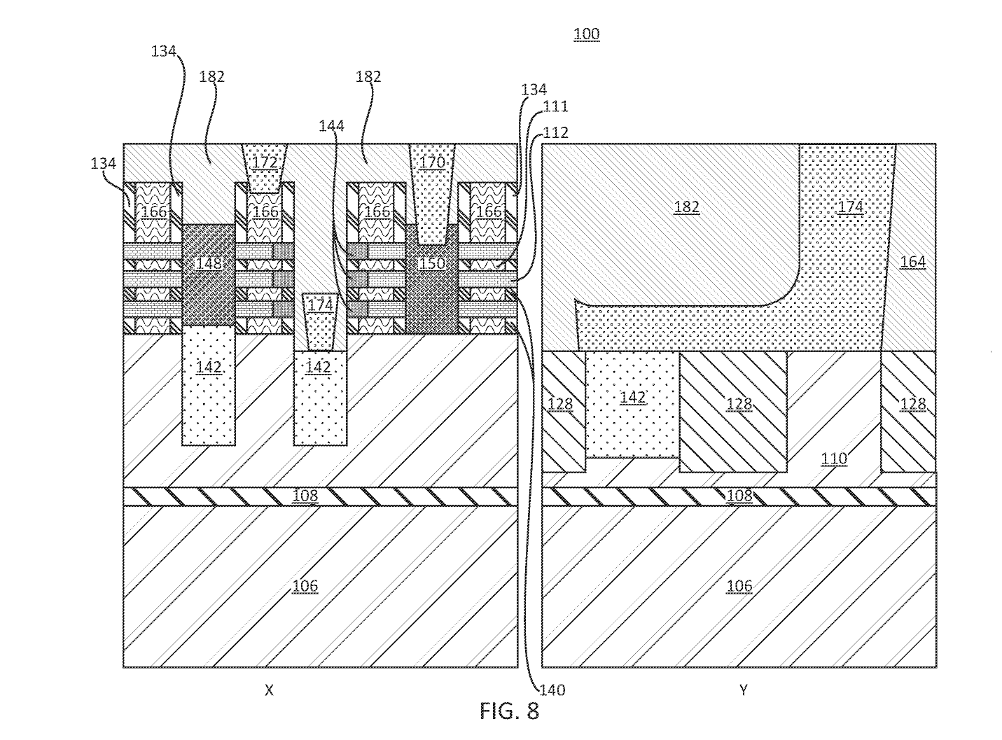

Referring to FIG. 8, the etch mask 180 is removed. The trenches 178 are refilled with a dielectric material 182. The dielectric material 182 can include a same or different material than that employed for the dielectric layer 164. After formation of the dielectric material 182, a planarization process (e.g., CMP) can be employed to remove access material and level of a free surface of the wafer 100.

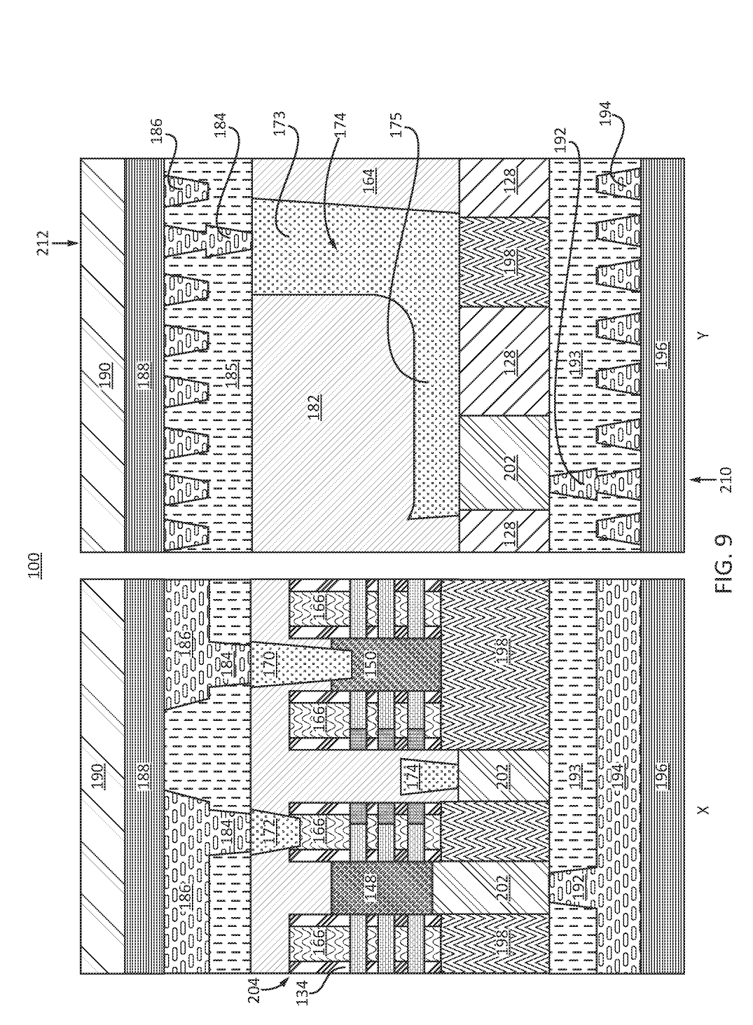

Referring to FIG. 9, another dielectric layer 185 is deposited over the wafer 100. The dielectric layer 185 is patterned to form openings for the formation of a vias 184 and metal lines 186. The openings are filled with one or more conductive fills and CMP processes, as needed. The vias 184 and metal lines 186 can be formed separately or together (e.g., in a dual damascene process). Processing continues with the formation of a back end of the line (BEOL) layer 188, which can include more or more metal structure layers and dielectric layers to complete a top side of the wafer 100. A carrier wafer 190 can be bonded to the BEOL layer 188. The carrier wafer 190 provides support and transportability to the wafer 100 for further processing which includes flipping the wafer 100 and removing portions of a bottom side of the device.

The wafer 100 can be flipped to process features on the bottom side of the device. However, for clarity and consistency, the stacked FET device will be shown in the FIGS. in a same orientation as previously described with continued and consistent reference to bottom/top or backside/frontside. The substrate 106 is removed from the bottom side of the wafer 100. The substrate 106 can be removed by an etch process that stops on the etch stop layer 108. The etch stop layer 108 is then removed by an etch process. In an alternate embodiment, a CMP process can be employed.

With the removal of the etch stop layer 108, the semiconductor layer 110 is exposed. The semiconductor layer 110 is removed by an etch process that selectively removes the material of the semiconductor layer 110 relative to the STI 128 and the sacrificial placeholders 142.

A dielectric layer 198 is formed over the STI 128, the sacrificial placeholders 142 and bottom portions of gate structures 204. The sacrificial placeholders 142 are exposed by recessing the dielectric layer 198. An etch process removes the sacrificial placeholders 142 leaving openings that expose the S/D regions 148 and the local interconnect 174.

A silicide liner, such as Ti, Ni, NiPt can be deposited first on the S/D regions 148 that have been exposed, then a diffusion barrier can be formed prior to a conductive fill. The diffusion barrier can include, e.g., TiN, TaN, or similar materials. The diffusion barrier can be included between the local interconnect 174 and the backside contact 202 as well. A conductive fill is performed to provide the backside contacts 202. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the backside contacts 202. The backside contacts 202 replace the sacrificial placeholders 142 and connect to a bottom side of selected S/D regions 150 or to the local interconnect 174.

A dielectric layer 193 is formed over the STI 128, the dielectric layer 198 and the backside contacts 202. The dielectric layer 193 is patterned to form openings for the formation of vias 192 and metal lines 194. The openings are filled with one or more conductive fills and CMP processes, as needed. The vias 192 and metal lines 194 can be formed separately or together (e.g., in a dual damascene process). Processing continues with the formation of a backside interconnect layer 196, which can include more or more metal structure layers and dielectric layers to complete a backside of the wafer 100. The backside interconnect layer 196 can be part of a backside power distribution network (BSPDN).

In accordance with embodiments of the present invention, the local interconnect 174 can provide a wiring connection between a first track 210 and a second track 212 which are laterally (horizontally) offset from one another. The local interconnect 174 can have the vertical portion 173 with a width less than or equal to a cell height of the track that it occupies. The horizontal portion 175 can extend over a number of tracks. The local interconnect 174 can connect to components on different layers and well as different tracks. In the exemplary embodiment shown, a conductive path is provided from the backside interconnect layer 196 through the metal line 194, the via 192, the backside contact 202, the local interconnect 174, the via 184, the metal line 186 to the BEOL layer 188. The formation of the local interconnect 174 is easily integrated within the fabrication process of a semiconductor device.

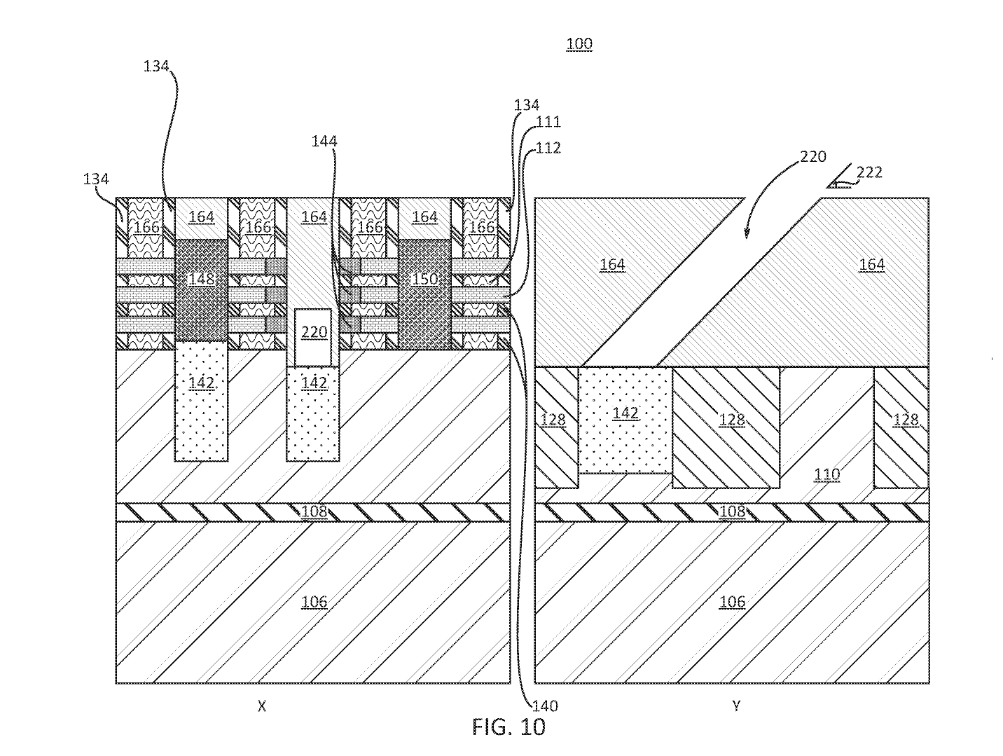

Referring to FIG. 10, in another embodiment, a tilted local interconnect 224 can be employed to provide a more direct connection (less metal to reduce capacitance) between offset tracks on a semiconductor device. Beginning with the structure depicted in FIG. 5, a lithographic process is employed to form an etch mask (not shown) on a surface of the dielectric layer 164.

An anisotropic etch process, e.g., is performed to form an opening 220 to expose the sacrificial placeholder 142. The opening 220 is formed on an angle 222 to create diagonal opening. The opening 220 can be formed by tilting the wafer 100 in a processing chamber (not shown) or by directing, e.g., reactive ions at the angle 222. The angle 222 is computed to span across tracks so that when filled with a conductor, the tilted local interconnect 224 will connect across offset tracks through one or more layers of the semiconductor device.

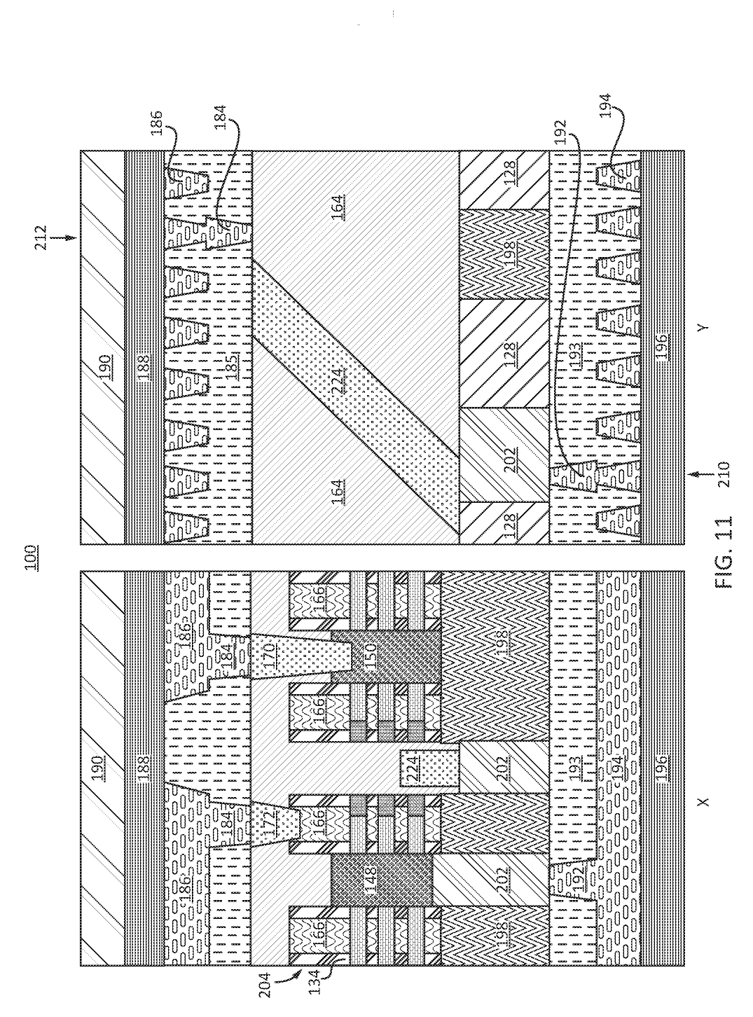

Referring to FIG. 11, a silicide liner, such as Ti, Ni, NiPt can be deposited first on the S/D regions 148 that have been exposed, then a diffusion barrier can be formed prior to a conductive fill. The diffusion barrier can include, e.g., TiN, TaN, or similar materials. A conductive fill is performed to form the tilted local interconnect 224. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the tilted local interconnect 224. Processing continues, as described.

In accordance with embodiments of the present invention, the tilted local interconnect 224 can provide a wiring connection between the first track 210 and the second track 212 which are laterally offset from one another. The tilted local interconnect 224 extends diagonally to span a horizontal portion and a vertical portion concurrently. The tilted local interconnect 224 minimizes material to further reduce capacitance.

The tilted local interconnect 224 diagonally connects across tracks and layers and can extend over a number of tracks and a number of layers. The tilted local interconnect 224 can connect at any acute angle. Said differently, the tilted local interconnect 224 can be disposed at an angle of between 0 and 90 degrees. The angle 222 can be between 0 and 90 degrees, and more particularly between 20 and 60 degrees. The angle 222 can be relative to a horizontal surface of the wafer 100. In the exemplary embodiment shown, a conductive path is provided from the backside interconnect layer 196 through the metal line 194, the via 192, the backside contact 202, the local interconnect 174, the via 184, the metal line 186 to the BEOL layer 188. The formation of the local interconnect 174 is easily integrated within the fabrication process of a semiconductor device.

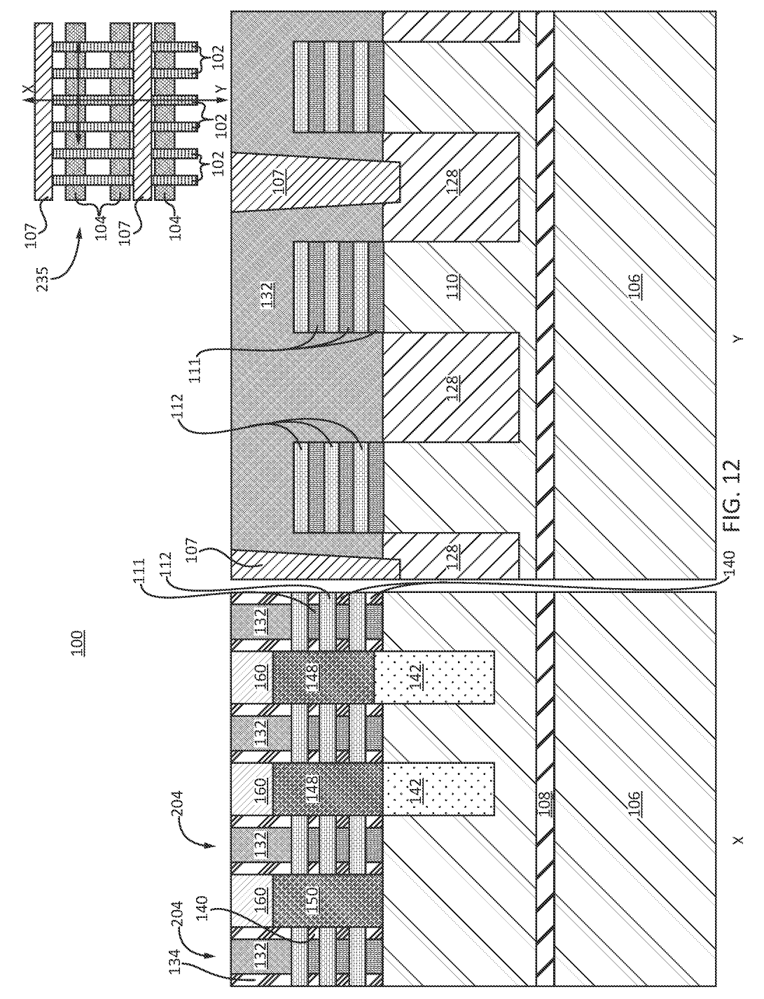

Referring to FIG. 12, in accordance with another embodiment, the structure of FIG. 1 is processed to form gate cuts 107. Gate cuts 107 are formed by etching cuts along lengths the gate structure 204 down to the STI 128 and filling the etched cuts with a dielectric material. Two orthogonal views X and Y taken at corresponding sections X and Y in an inset 235 are shown. Inset 235 shows gate lines 102 and active region lines 104 for reference. Corresponding X and Y views are depicted throughout the FIGS. Active region lines 104 represent S/D regions for transistor devices to be formed, and gate lines 102 are represented for such transistor devices. Transistor channels are formed on the active region lines 104 below the gate lines 102. Gate cuts 107 are also depicted in the inset 235.

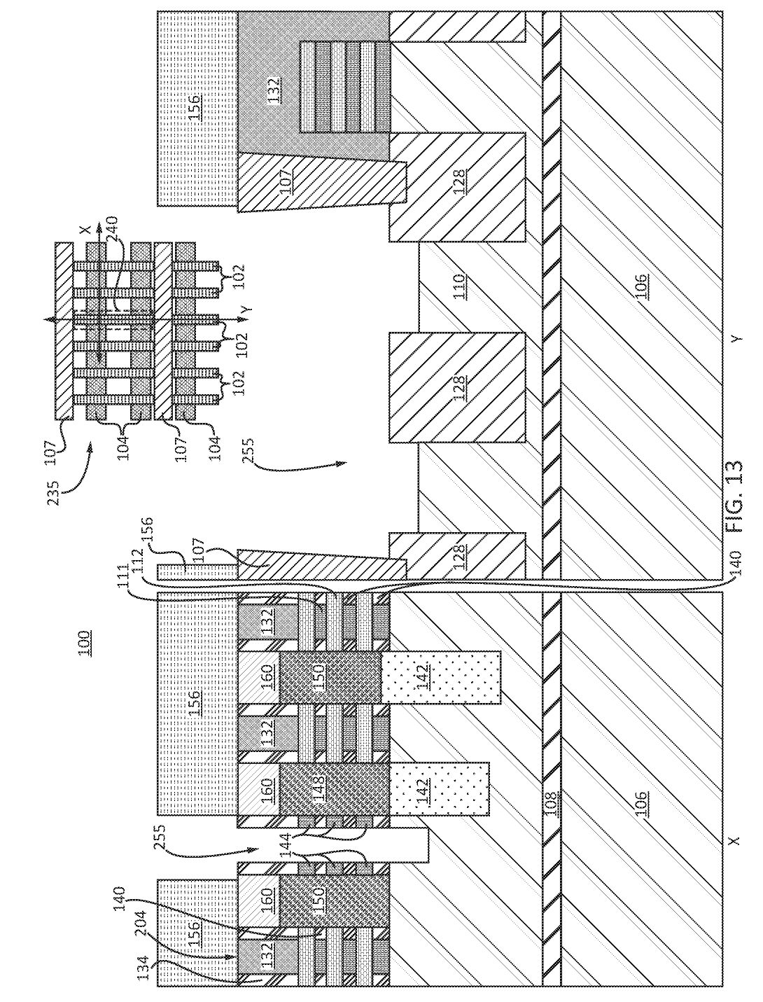

Referring to FIG. 13, the etch mask 156 is formed on a surface of the wafer 100. In an embodiment, the etch mask 156 can include an organic polymer layer (OPL). In some embodiments, an anti-reflective coating (ARC) layer (not shown) may be formed on the OPL of the etch mask 156 followed by a layer of photoresist formed on the ARC layer. The layer of photoresist can be imaged with an image pattern and developed to form an etch mask.

The OPL of the etch mask 156 can be etched in accordance with the photoresist pattern to open up a single diffusion break cut 255 through the OPL of the etch mask 156 and remove dummy gate material 132 along the single diffusion break cut 255. The single diffusion break cut 255 can be formed by an anisotropic etch, e.g., a RIE etch or IBE etch. Etching of the OPL of the etch mask 156 in accordance with the etch mask may include an etch chemistry for removing the OPL of the etch mask 156, the dummy gate material 132 and recessing the semiconductor layer 110. The etch mask 156 is removed. If the etch mask 156 includes OPL, an ashing process can be employed to remove the OPL.

The single diffusion break cut 255 is selectively etched to laterally recess the nanosheets 112. The recesses formed are then filled with a dielectric material by performing a dielectric deposition. The dielectric deposition (e.g., CVD) forms a dielectric material in the recesses. An etch process removes any residual dielectric material (e.g., an oxide) from the dielectric deposition to form inner spacers 144.

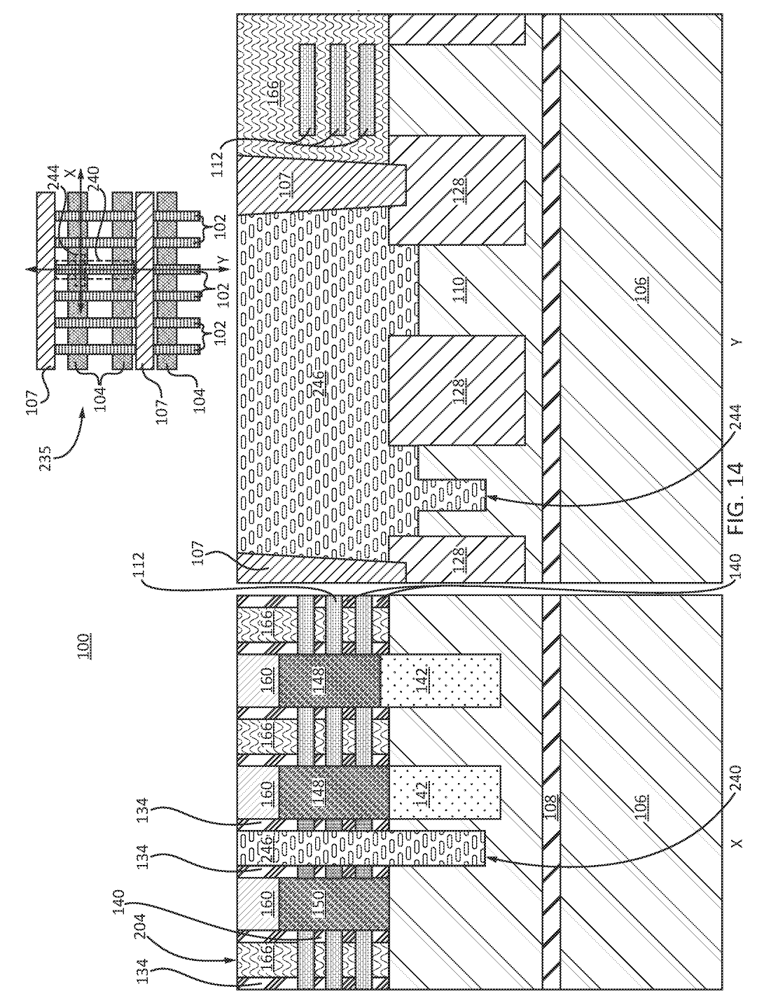

The single diffusion break cut 255 is then further extended deeper into the semiconductor layer 110 by etching to form an extension 240 and a cross bar 244 (see inset 235 in FIG. 14). The single diffusion break cut 255 is etched by removing the etch mask 156 and applying a block mask (not shown) in other regions. The block mask can be patterned and etching employed to extend the depth and shape of the single diffusion break cut 255 into the semiconductor layer 110.

Referring to FIG. 14, the dummy gate material 132 and the nanosheets 111 are removed by etching. This can include separate etch processes. The regions of the dummy gate material 132 and the nanosheets 111 have a high-K gate dielectric (not shown) deposited followed by a gate metal fill to form the gate conductors 166 by an RMG process. A planarization process (e.g., CMP) can be employed to planarize a free surface of the wafer 100.

A plug can be provided in the single diffusion break cut 255 during the gate replacement process. After the plug is removed, a conductive fill is performed to fill the single diffusion break cut 255 including the extension 240 and the cross bar 244 on top of the diffusion barrier, if present. The conductive fill can include materials, such as, e.g., Cu, Ru, Mo, Rh, W, Ir, and alloys or combinations of these and other conductive materials. The conductive fill can be formed using a deposition method, such as, e.g., CVD, PECVD, ALD or any other suitable deposition method. The conductive fill is planarized, e.g., by CMP, to form an interconnect structure 246.

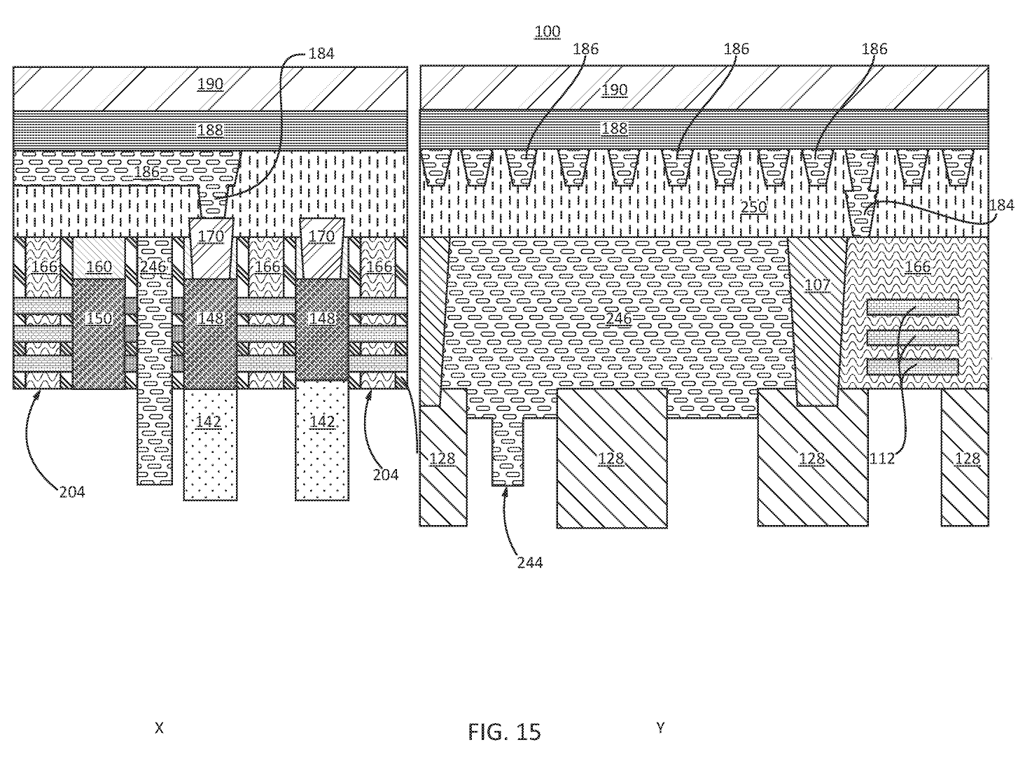

Referring to FIG. 15, MOL contacts are formed to make connections with gate conductors 166, S/D region 150 (and S/D regions 148 in other regions) and the sacrificial placeholders 142. A dielectric layer 250 is deposited over the wafer 100. Trenches or holes are formed through the dielectric layer 250. The trenches or holes expose the underlying components to be contacted.

In useful embodiments, a silicide liner, such as Ti, Ni, NiPt is deposited first where contacts connect to S/D regions 148 and 150. A diffusion barrier can be formed in all trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form contacts 170.

The dielectric layer 250 is extended by the addition of dielectric material. The dielectric layer 250 is patterned to form openings for the formation of the vias 184 and metal lines 186. The openings are filled with one or more conductive fills and CMP processes, as needed. Processing continues with the formation of the BEOL layer 188, which can include one or more metal structure layers and dielectric layers to complete a top side of the wafer 100. The carrier wafer 190 can be bonded to the BEOL layer 188. The carrier wafer 190 provides support and transportability to the wafer 100 for further processing which includes flipping the wafer 100 and removing portions of a bottom side of the device.

The wafer 100 can be flipped to process features on the bottom side of the device. However, for clarity and consistency, the stacked FET device will be shown in the FIGS. in a same orientation as previously described with continued and consistent reference to bottom/top. The substrate 106 is removed from the bottom side of the wafer 100. The substrate 106 can be removed by an etch process that stops on the etch stop layer 108. The etch stop layer 108 is then removed by an etch process. In an alternate embodiment, a CMP process can be employed.

With the removal of the etch stop layer 108, the semiconductor layer 110 is exposed. The semiconductor layer 110 is removed by an etch process that selectively removes the material of the semiconductor layer 110 relative to the STI 128, the interconnect structure 246 and the sacrificial placeholders 142.

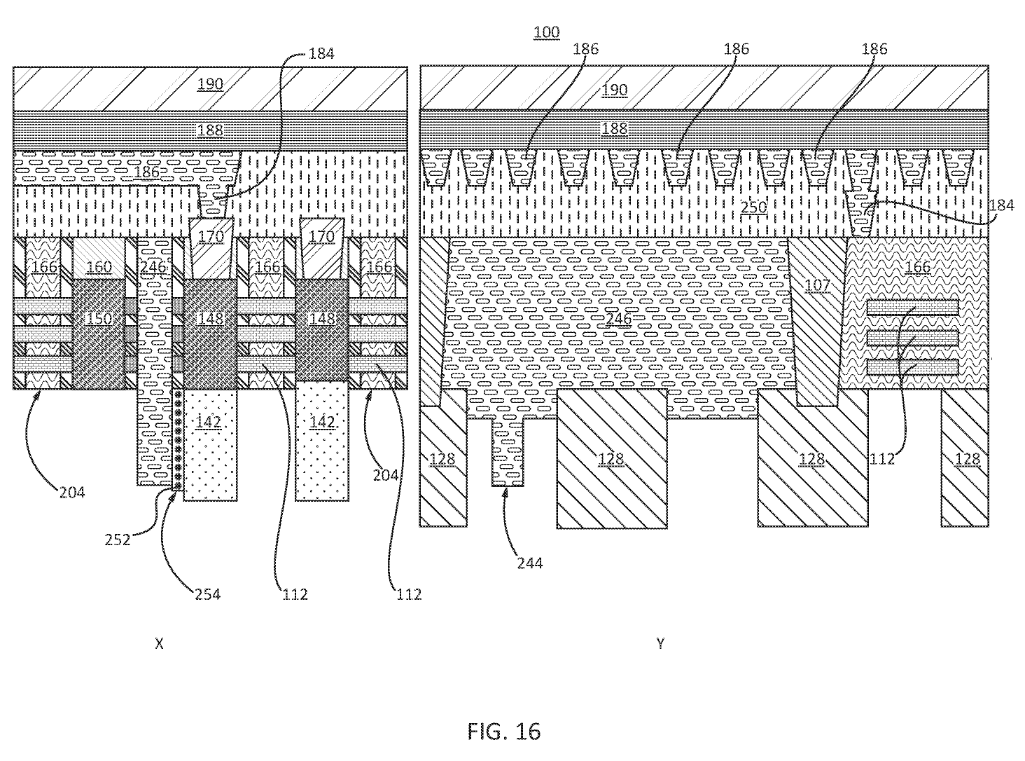

Referring to FIG. 16, a deposition process is performed on a backside of the wafer 100 to conformally deposit a dielectric material. The dielectric material can be deposited by, e.g., an ALD process to fill in a gap 254 between the interconnect structure 246 and the sacrificial placeholder 142. The deposition of the dielectric material pinches off an opening of the gap 254. An atomic layer etching (ALE) process can be performed to remove the dielectric material. Since the dielectric material in the gap 254 is pinched off, the ALE process does not remove the dielectric material in the gap 254 leaving a plug 252 in the gap 254.

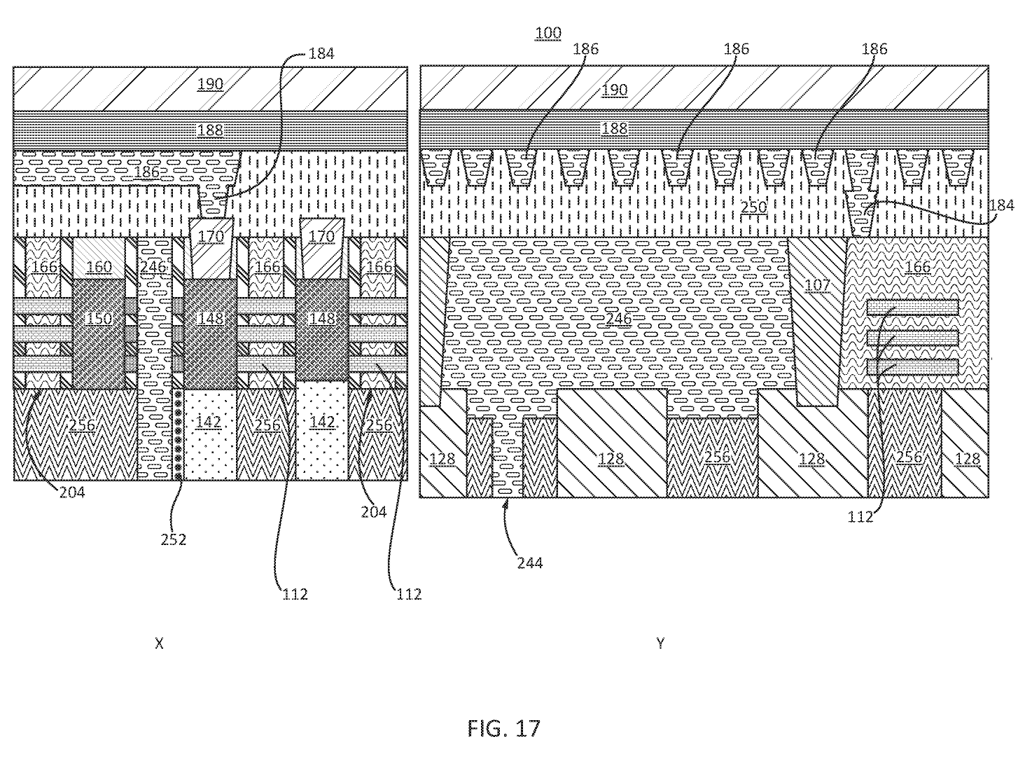

Referring to FIG. 17, a dielectric layer 256 is formed over the STI 128, the sacrificial placeholders 142, the plug 252, extension 240, cross bar 244 and bottom portions of gate structures 204. The sacrificial placeholders 142, the plug 252, the extension 240 and the cross bar 244 of the interconnect structure 246 are exposed by recessing the dielectric layer 256. The dielectric layer 256 can be recessed, e.g., by CMP.

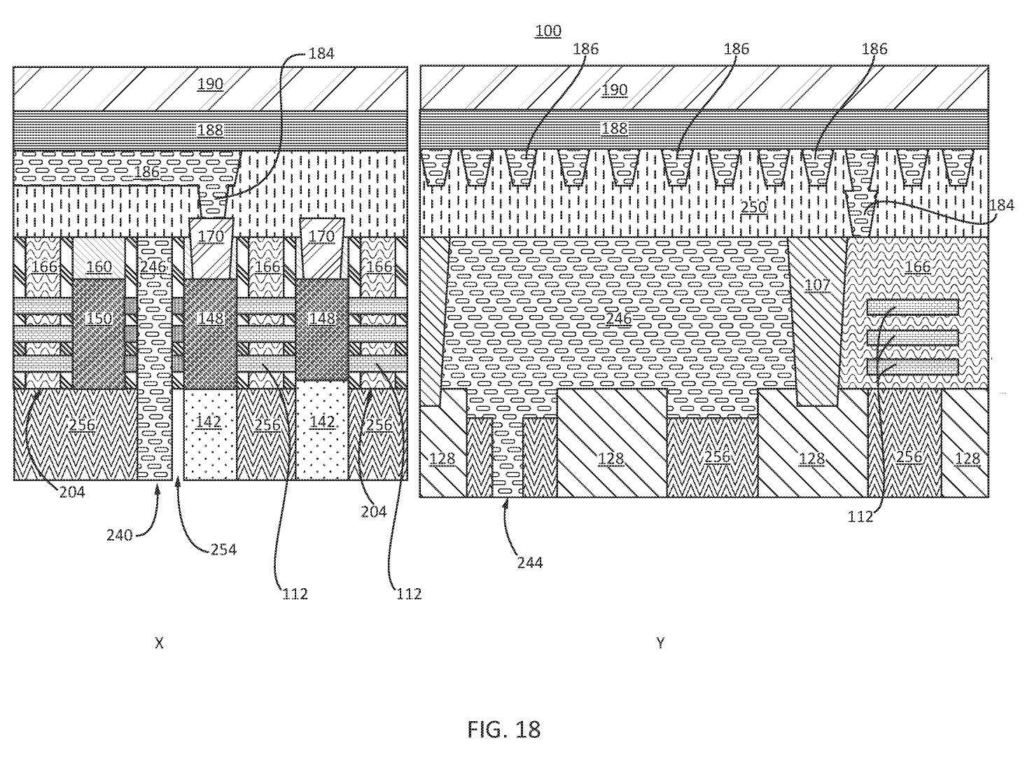

Referring to FIG. 18, the plug 252 is removed by a selective etch process. The selective etch removed the dielectric material of the plug 252 to reform the gap 254 between the sacrificial placeholder and the interconnect structure 246.

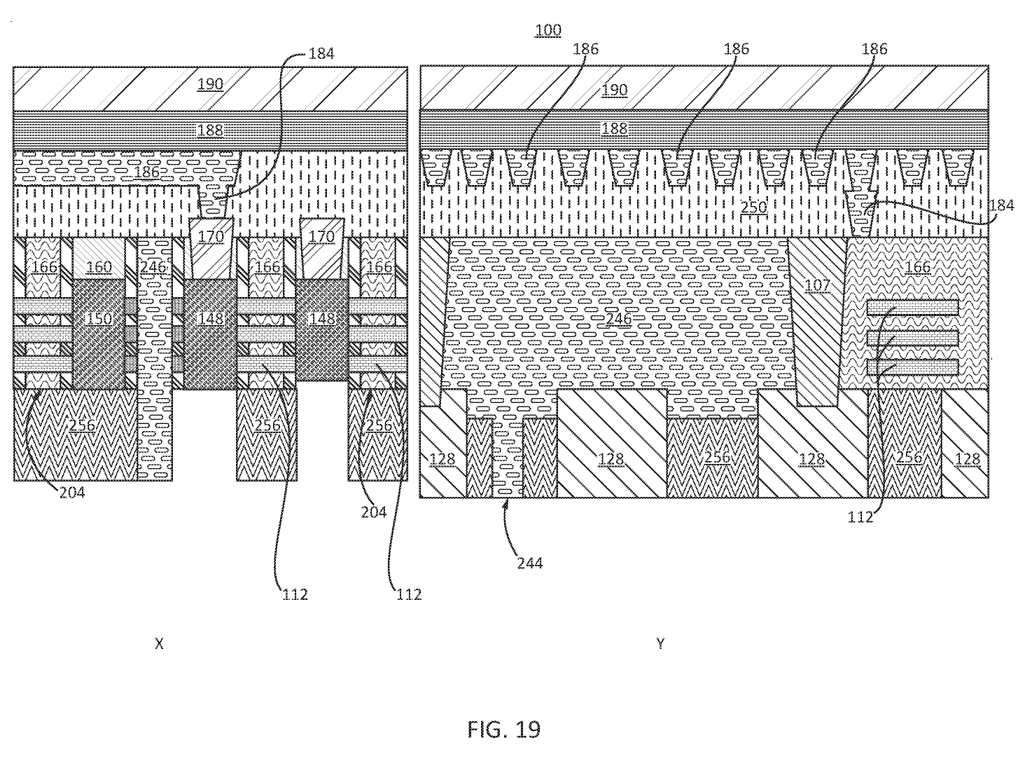

Referring to FIG. 19, an etch process removes the sacrificial placeholders 142 leaving openings that expose the S/D regions 148. The opening left by the sacrificial placeholder 142 adjacent to the gap 254 exposes the interconnect structure 246 through the opening left by the sacrificial placeholder 142. The opening left by the sacrificial placeholder 142 and the gap 254 provide a wider space that exposes the S/D region 148 corresponding thereto.

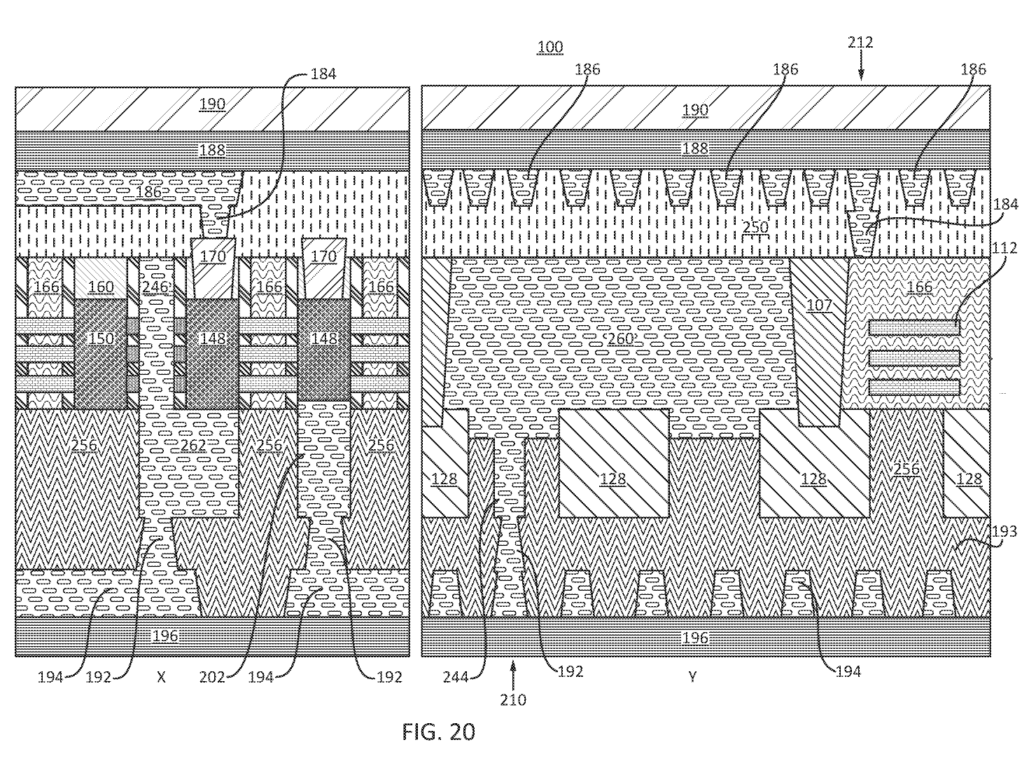

Referring to FIG. 20, a silicide liner, such as Ti, Ni, NiPt can be deposited first on the S/D regions 148 that have been exposed from the backside of the wafer 100, then a diffusion barrier can be formed prior to a conductive fill. The diffusion barrier can include, e.g., TiN, TaN, or similar materials. The diffusion barrier can be included before forming the backside contact 202 and an extended lateral contact 262 to be formed. A conductive fill is performed to provide the backside contacts 202 and the extended lateral contact 262. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the backside contacts 202 and extended lateral contact 262. The backside contacts 202 and the extended lateral contact 262 replace the sacrificial placeholders 142 and connect to a bottom side of selected S/D regions 148.

The extended lateral contact 262 combined with the interconnect structure 246 form an angled conductor 260 that occupies a gate canyon and connects with a bottom of the S/D region 148 adjacent to the gate canyon. The angled conductor 260 connects conductors on different tracks. The interconnect structure 246 extends between source/drain regions and runs parallel to gate lines. The extended lateral contact 262 connects to the interconnect structure 246 (forming in L-shape in section X) and extends perpendicularly to the gate lines on a backside of the semiconductor device. The interconnect structure 246 is disposed within a diffusion break cut between source/drain regions 148 and 150, and the angled conductor 260 provides an electrical path through the source/drain region 148. The cross bar 244 can connect to a via 192 (or backside contact).

The dielectric layer 193 is formed over the STI 128, the dielectric layer 256, the backside contacts 202 and the extended lateral contact 262. The dielectric layer 193 is patterned to form openings for the formation of the vias 192 and the metal lines 194. The openings are filled with one or more conductive fills and CMP processes, as needed. Processing continues with the formation of the backside interconnect layer 196, which can include more or more metal structure layers and dielectric layers to complete a backside of the wafer 100. The backside interconnect layer 196 can be part of a BSPDN.

In accordance with embodiments of the present invention, the angled conductor 260 can provide a wiring connection between the first track 210 and the second track 212 which are laterally offset from one another. The angled conductor 260 permits multiple connection points. These can include vertical and horizontal connections. The angled conductor 260 can include a horizontal portion that can extend over a number of tracks. The angled conductor 260 can connect to components on different layers as well as different tracks. In the exemplary embodiment shown, a conductive path is provided from the backside interconnect layer 196 through the metal line 194, the via 192, the extended lateral contact 262, the S/D region 148, the contact 170, the via 184, the metal line 186 to the BEOL layer 188.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a frontside and a backside;
a first conductor on the frontside disposed in a first track;
a second conductor on the backside disposed in a second track which is offset from the first track; and
a local interconnect connecting the first conductor to the second conductor, the local interconnect including:
a vertical portion that connects components on different layers; and
a horizontal portion extending laterally from the vertical portion and extending between the first track and the second track.

2. The semiconductor device of claim 1, wherein the vertical portion has a width less than or equal to a cell height of a track that the vertical portion occupies.

3. The semiconductor device of claim 1, wherein the horizontal portion extends over multiple tracks.

4. The semiconductor device of claim 1, further comprising:
a backside interconnect layer; and
a frontside back end of line (BEOL) layer, wherein the local interconnect provides a conductive path between the backside interconnect layer and the frontside BEOL layer.

5. The semiconductor device of claim 1, wherein the local interconnect includes a tilted local interconnect wherein the horizontal portion and the vertical portion extend diagonally to connect the first conductor to the second conductor.

6. The semiconductor device of claim 5, wherein the tilted local interconnect is disposed at an angle between 0 and 90 degrees relative to a horizontal surface.

7. The semiconductor device of claim 1, wherein the vertical portion includes a width larger than a height of the horizontal portion.

8. The semiconductor device of claim 1, wherein the local interconnect includes an L-shape to reduce capacitance.

9. The semiconductor device of claim 1, wherein the vertical portion and the horizontal portion are integrally formed.

10. A semiconductor device, comprising:
a frontside and a backside;
a first conductor on the frontside disposed in a first track;
a second conductor on the backside disposed in a second track which is offset from the first track; and
a local interconnect connecting the first conductor to the second conductor, the local interconnect including a horizontal portion that connects a backside contact to a vertical portion of the local interconnect, the horizontal portion extending laterally over multiple tracks to connect between the first conductor in the first track and the second conductor in the second track.

11. The semiconductor device of claim 10, wherein the vertical portion has a width less than or equal to a cell height of a track that it occupies.

12. The semiconductor device of claim 10, further comprising:
a backside interconnect layer; and
a frontside back end of line (BEOL) layer, wherein the local interconnect provides a conductive path between the backside interconnect layer and the frontside BEOL layer.

13. The semiconductor device of claim 10, wherein the local interconnect includes a tilted local interconnect wherein the horizontal portion and the vertical portion extend diagonally to connect the first conductor to the second conductor.

14. The semiconductor device of claim 13, wherein the tilted local interconnect is disposed at an angle between 0 and 90 degrees relative to a horizontal surface.

15. The semiconductor device of claim 10, wherein the vertical portion includes a width larger than a height of the horizontal portion.

16. The semiconductor device of claim 10, wherein the local interconnect includes an L-shape to reduce capacitance.

17. The semiconductor device of claim 10, wherein the vertical portion and the horizontal portion are integrally formed.

18. A method of forming a semiconductor device, comprising:
forming a diffusion break cut through a source/drain region;
depositing a conductive material in the diffusion break cut;
forming the conductive material to extend horizontally and vertically to connect horizontally offset components in different layers; and
connecting a first conductor disposed in a first track on a frontside of the semiconductor device to a second conductor on a backside of the semiconductor device disposed in a second track which is offset from the first track.

19. The method of claim 18, further comprising subtractively etching a portion of the conductive material to form an L-shaped local interconnect from the conductive material, the L-shaped local interconnect having a vertical portion and a horizontal portion, the horizontal portion extending laterally over multiple tracks from the vertical portion.

20. The method of claim 18, further comprising forming the conductive material on an angle to provide a tilted local interconnect that extends horizontally and vertically to connect horizontally offset components.
